(19) United States
(12) Patent Application Publication
(10) Pub. No.: US 2017/0290142 A1
(43) Pub. Date: Oct. 5, 2017

(54) ELECTRONIC PARTS

(71) Applicant: SAMSUNG ELECTRONICS CO., LTD., Suwon-si (KR)

(72) Inventors: Sung-yong JOO, Hwaseong-si (KR); Jin-hyung LEE, Anyang-si (KR); Jung-ho LEE, Uijeongbu-si (KR)

(21) Appl. No.: 15/413,817

(22) Filed: Jan. 24, 2017

(30) Foreign Application Priority Data
Mar. 29, 2016 (KR) 10-2016-0037601

(51) Int. Cl. H05K 1/02; H01F 27/24; H01F 27/29; H03H 1/00; H01F 27/06

(52) U.S. Cl. CPC H05K 1/0233; H03H 1/00; H01F 27/06; H01F 27/29; H01F 27/24; H03H 2001/0092; H03H 2001/0057; H01F 2027/065

(57) ABSTRACT

Electronic parts for improving an isolation distance are provided. The electronic part includes: at least one plate; and first and second terminals each connected to the plate, wherein the electronic part is mounted in a PCB through the first and second terminals and a creepage distance between the first terminal and the second terminal is greater than a clearance distance between the first terminal and the second terminal.

### CROSS-REFERENCE TO RELATED APPLICATION

This application is based on and claims priority under 35 U.S.C. §119 to Korean Patent Application No. 10-2016-0037601, filed on Mar. 29, 2016 in the Korean Intellectual Property Office, the disclosure of which is incorporated by reference herein in its entirety.

### BACKGROUND

### Field

The present disclosure relates generally to electronic parts for improving an isolation distance.

### Description of Related Art

As electronic products tend to be miniaturized, slimmed, highly densified, packaged, and personally carried, a printed circuit board (PCB) is also miniaturized and packaged.

Generally, a semiconductor package is configured to include a lead frame, a power semiconductor device mounted on the lead frame, and a mold part molding an outside of each device with resin, or the like.

A heat sink is attached to radiate heat of the semiconductor package using a high voltage. In this case, an electrical short between the lead frame and the heat sink may occur.

Therefore, to prevent and/or avoid the electrical short between the lead frame and the heat sink, there is a need to secure a predetermined isolation distance.

With the recent demand for miniaturization and weight reduction of the semiconductor package, researches for the semiconductor package that does not have a limitation of the isolation distance without increasing the size of the semiconductor package are required.

### SUMMARY

Example embodiments of the present disclosure address the above disadvantages and other disadvantages not described above.

The present disclosure provides electronic parts meeting a standard of an isolation distance.

According to an example aspect of the present disclosure, an electronic part includes: at least one plate-like element; and first and second terminals each connected to the plate-like element, wherein the electronic part is mounted in a PCB through the first and second terminals and a creepage distance between the first terminal and the second terminal is greater than a clearance distance between the first terminal and the second terminal.

The plate-like element may have an oval shape.

The plate-like element further may include: a first electrode layer formed on one surface of the plate-like element; and a second electrode layer formed on another side surface of the plate-like element different than the surface on which the first electrode layer is formed.

The first terminal may be connected to the first electrode layer and the second terminal may be connected to the second electrode layer.

The first terminal may include a first connecting end portion connected to the first electrode layer and a first bending portion extending from the first connecting part and configured to be bent toward the PCB; and the second terminal may include a second connecting end portion connected to the second electrode layer and a second bending portion extending from the second connecting part and configured to be bent toward the PCB.

The plate-like element may have a long axis in a vertical direction with respect to the first and second bending parts.

The electronic part may further include: a first filter into which a portion of the first terminal is inserted and a second filter into which a portion of the second terminal is inserted.

The first and second filters may comprise a ferrite core.

The plate-like element may include: a first plate-like element including a first electrode layer formed on one surface thereof and a second electrode layer formed on another surface of the first plate-like element different from the surface on which the first electrode layer is formed; and a second plate-like element including a third electrode layer formed on one surface thereof and a fourth electrode layer formed on another surface of the second plate-like element, and the first terminal may be connected to the first plate-like element and the second terminal may be connected to the second plate-like element.

The electronic part may further include: a connecting terminal connecting the first plate-like element and the second plate-like element in series.

The first electrode layer and the third electrode layer may have the same polarity and the second electrode layer and the fourth electrode layer may have the same polarity different from the first electrode layer.

The connecting terminal may be connected to the second electrode layer and the third electrode layer, the first terminal may be connected to the first electrode layer, and the second terminal may be connected to the fourth electrode layer.

The first plate-like element and the second plate-like element may have a disk shape and may be disposed to correspond to each other.

The first plate-like element and the second plate-like element may be positioned at a preset interval.

The electronic part may further include: a connecting terminal connecting the first plate-like element and the second plate-like element in series, wherein the connecting terminal may include a coil portion provided between the first plate-like element and the second plate-like element.

The electronic part may further include: a first filter into which the first terminal is inserted; and a second filter into which the second terminal is inserted.

The first and second filter members may comprise a ferrite core.

The creepage distance may be 1.48 times or greater than the clearance distance.

The first bending part and the second bending part may be positioned at the same distance from a center of the plate-like element part.

A portion of the first and second bending parts may be inserted into the first and second filters, respectively.

### BRIEF DESCRIPTION OF THE DRAWINGS

The above and/or other aspects, features and attendant advantages of the present disclosure will be more apparent and readily understood from the following detailed description, taken in conjunction with the accompanying drawings, in which like reference numerals refer to like elements, and wherein:

FIG. 1 is a perspective view illustrating example electronic parts according to an example embodiment of the present disclosure;

FIG. 2 is a front view illustrating example electronic parts according to an example embodiment of the present disclosure;

FIG. 3 is a side view illustrating example electronic parts according to an example embodiment of the present disclosure;

FIG. 4 is a front view illustrating an example state in which the electronic parts according to an example embodiment of the present disclosure are mounted in a PCB;

FIG. 5 is a front view illustrating example electronic parts according to another example embodiment of the present disclosure;

FIG. 6 is a plan view illustrating example electronic parts viewed in direction A-A′ illustrated in FIG. 5;

FIG. 7 is a front view illustrating example electronic parts according to another example embodiment of the present disclosure; and

FIG. 8 is a front view illustrating example electronic parts according to another example embodiment of the present disclosure.

### DETAILED DESCRIPTION

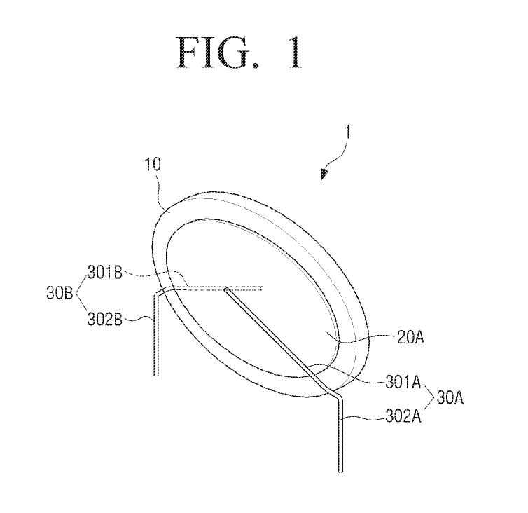

Hereinafter, various example embodiments of the present disclosure will be described in greater detail with reference to FIGS. 1 to 8. The following example embodiments will be described based on example embodiments appropriate to understand technical features of the present disclosure and the technical features of the present disclosure are not limited to the example embodiments to be descried below but it is illustrated that the present disclosure may be implemented like example embodiments to be described.

Therefore, the present disclosure may be variously changed within the technical scope of the present disclosure in accordance with the example embodiments to be described below and the changed example embodiments may be considered to be included in the technical scope of the present disclosure. Further, to help understand the following example embodiments, in signs described in the accompanying drawing, relevant components among components performing the same operations in each example embodiment are denoted by reference numerals on the same or extending line.

As long as electronic parts according to example embodiments described below have a structure in which at least two terminals are mounted in a plate-like element, any electronic parts such as a capacitor, a varistor, and a thermistor may be used.

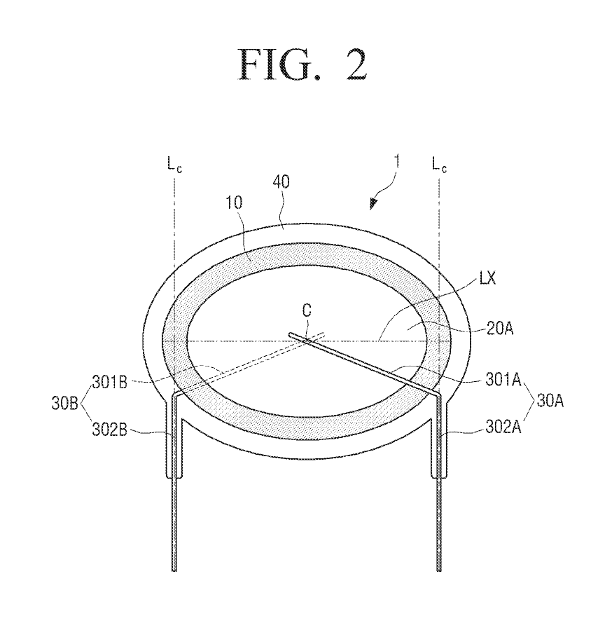

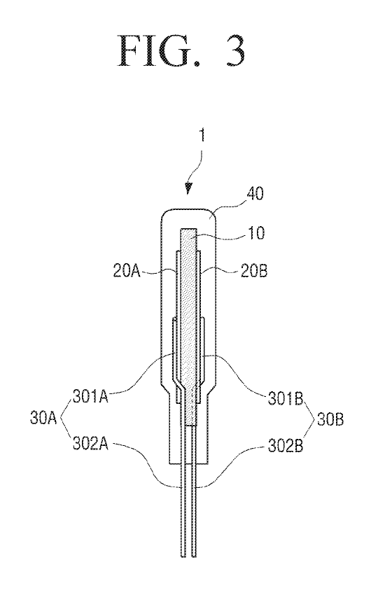

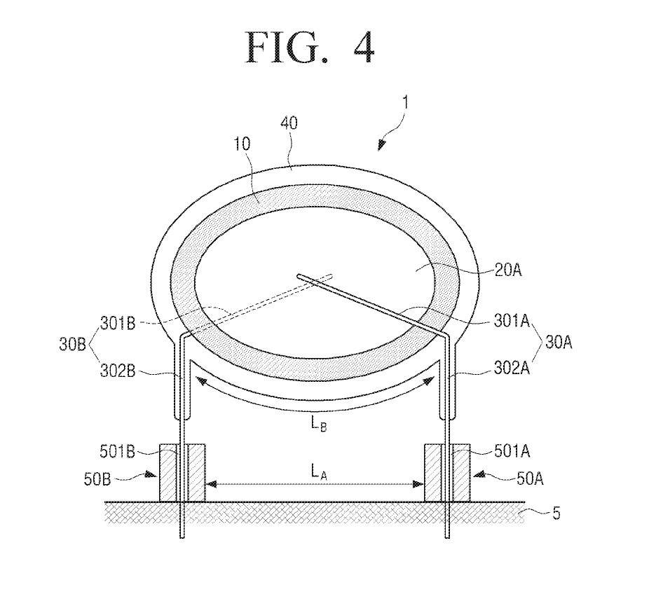

FIG. 1 is a perspective view schematically illustrating example electronic parts according to an example embodiment of the present disclosure and FIG. 2 is a perspective view illustrating example electronic parts according to an example embodiment of the present disclosure. FIG. 3 is a side view illustrating example electronic parts according to the example embodiment of the present disclosure and FIG. 4 is a front view illustrating an example state in which the electronic parts according to an example embodiment of the present disclosure are mounted in a PCB.

Referring to FIGS. 1 to 4, an electronic part 1 according to an example embodiment of the present disclosure may include one plate-like element part 10, a first electrode layer 20A, a second electrode layer 20B, a first terminal 30A, a second terminal 30B, and a coating member 40.

The plate-like element part 10 according to an example embodiment of the present disclosure may have an oval shape, but is not limited thereto. The plate-like element part 10 may have an oval shape having a long axis LX in a vertical direction with respect to a virtual line L_{C} passing a first bending part 302A and a second bending part 302B.

The plate-like element part 10 may be a ceramic element that is a dielectric substance. For example, the plate-like element part 10 may be formed by plasticity of a ceramic green sheet including a ceramic powder, an organic solvent, and an organic binder. The ceramic powder which is a high-k material may be a barium titanate (BaTiO₃) based material, a strontium titanate (SrTiO₃) based material, or the like. As another example, the plate-like element part 10 may also be manufactured by mixing zinc oxide, bismuth, cobalt, manganese, nickel, or the like in an oxide form at a predetermined ratio and drying them and then press molding them in an oval shape.

In this case, one surface of the plate-like element part 10 may be printed with a first electrode layer 20A and the other surface of the plate-like element part 10 may be printed with a second electrode layer 20B. The first and second electrode layers 20A and 20B may be formed of conductive pastes including conductive metal. For example, the conductive metal may be nickel, copper, palladium, or an alloy thereof, but is not limited thereto.

The first terminal 30A may include a first connecting part 301A connected to the first electrode layer 20A and a first bending part 302A connected to the first connecting part 301A. The second terminal 30B may include a second connecting part 301B connected to the second electrode layer 20B and a second bending part 302B connected to the second connecting part 301B.

The first connecting part 301A may be connected to the first electrode layer 20A by soldering and the second connecting part 301B may be connected to the second electrode layer 20B by soldering. The first bending part 302A may be bent with respect to the first connecting part 301A at a preset angle and the second bending part 302B may be bent with respect to the second connecting part 301B at a preset angle.

In this case, the bending angles of the first bending part 302A and the second bending part 302B may be equal to each other. The first bending part 302A and the second bending part 302B may be bent in approximately the vertical direction with respect to the PCB 5 to be easily inserted into the PCB 5 (refer to FIG. 4). The first terminal 30A and the second terminal 30B may be manufactured using a copper wire coated with nickel, a copper wire coated with tin, or the like.

The electronic part 1 may further include a coating or coated member 40 that partially encloses the first terminal 30A and the second terminal 30B simultaneously with enclosing the whole of the plate-like element part 10, the first electrode layer 20A, the second electrode layer 20B, and the second electrode layer 20B. The coated member 40 may have an oval shape corresponding to an outer circumferential surface of the plate-like element part 10. In this case, the coated member 40 may be manufactured to isolate between the plate-like element part 10 and the electrode layers 20A and 20B while considering aesthetics. The coated member 40 may be generally made of powder epoxy and liquid paint and an isolating material may also be made of ceramics.

Referring to FIG. 4, the electronic part 1 may further include first and second filter members 50A and 50B. The first bending part 302A of the first terminal 30A is inserted into a first insertion hole 501A formed in the first filter member 50A and the second bending part 302B of the second terminal 30B is inserted into a second insertion hole 501B formed in the second filter member 50B. The first and second filter members 50A and 50B may be made of a ferrite core (or ferrite bead, electromagnetic compatibility (EMC) core).

The ferrite bead is a part having a bead form made of a ferrite material and may have a small cylindrical shape. The ferrite bead includes both a resistor component and an inductor component. The ferrite bead acts as a general wire in a low frequency band but acts as an inductor while having high impedance in a high frequency band. Therefore, the ferrite bead may serve as a filter that removes a noise signal in a high frequency band.

For example, the first and second filter members 50A and 50B may be formed so that a noise signal of a band (500 KHz to 100 MHz) having good permeability in a cylindrical ferrite core may be consumed in a shorted form and an effective signal not belonging to the band may pass without loss. The first and second filter members 50A and 50B serve as a filter that prevents a high frequency in an RF and therefore may perform RF choke and attenuate an electromagnetic interference (EMI).

A short may occur due to a discharge or the like between the first terminal 30A and the second terminal 30B. To prevent and/or avoid this, there is a need to secure a preset isolation distance. Here, the isolation distance may be divided into a clearance distance L_{A} and a creepage distance L_{B}. Therefore, the electronic component 1 according to an example embodiment of the present disclosure needs to secure the sufficient clearance distance L_{A} and creepage distance L_{B} depending on the rated voltage.

As described above, the plate-like element part 10 has approximately an oval shape as illustrated in FIG. 2. The plate-like element part 10 may have the long axis LX in the vertical direction with respect to the virtual line LC passing the first bending part 302A and the second bending part 302B. The plate-like element part has an oval shape, and thus the creepage distance L_{B} is formed to be longer than the clearance distance as compared with when the plate-like element part has a circle as illustrated in FIG. 4. As a result, in the electronic component 1 according to an example embodiment of the present disclosure, the isolation distance between the first terminal 30A and the second terminal 30B may be improved structurally.

For example, when the clearance distance L_{A} is 4 mm, the creepage distance L_{B} may be 1.48 times or more greater than the clearance distance. That is, the plate-like element part 10 has an oval shape, and as a result the creepage distance L_{B} may secure a distance that is equal to or more than 5.92 mm. As another example, when the clearance distance L_{A} is equal to or more than 2 mm, the creepage distance L_{B} may be equal to or more than 2.96 mm of the clearance distance.

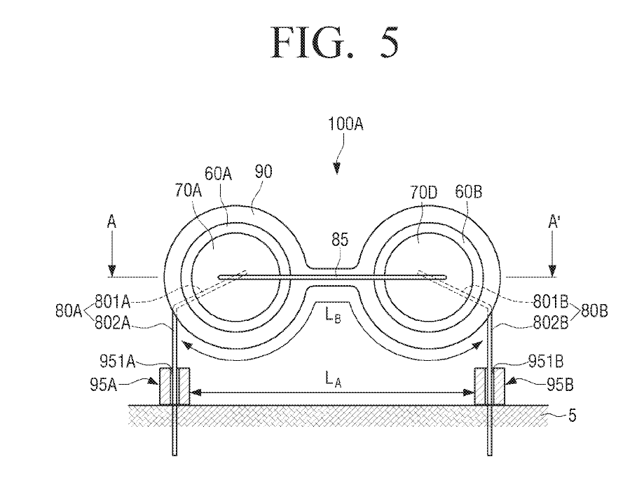

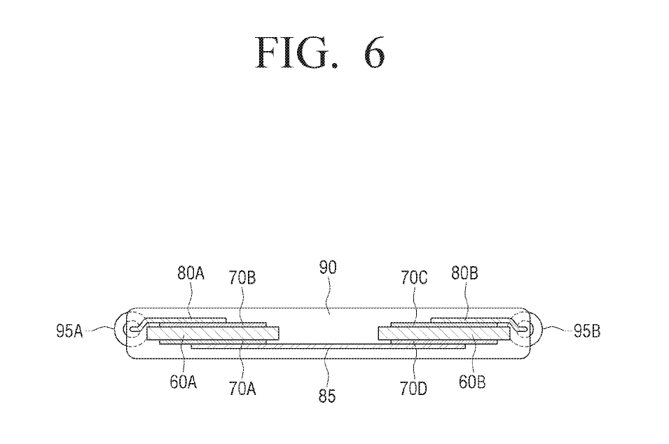

FIG. 5 is a front view illustrating example electronic parts according to another example embodiment of the present disclosure and FIG. 6 is a plan view illustrating the example electronic parts viewed in direction A-A′ illustrated in FIG. 5. Hereinafter, a difference between an electronic component 100A according to another example embodiment of the present disclosure and the electronic component 1 according to the previous example embodiment of the present disclosure will be mainly described and the omitted description may be replaced by the foregoing content with reference to FIGS. 1 to 4.

Referring to FIGS. 5 and 6, the plate-like element part may include a first plate-like element 60A and a second plate-like element 60B positioned to be spaced apart from the first plate-like element 60A at a preset interval. The first plate-like element 60A and the second plate-like element 60B may have a disk shape and the first plate-like element 60A and the second plate-like element 60B may have the same shape and may be disposed at a position where they correspond to each other.

The first plate-like element 60A may have a first electrode layer 70A formed on one surface thereof and have a second electrode layer 70B formed on the other side surface thereof. The second plate-like element 60B may have a third electrode layer 70C formed on one surface thereof and have a fourth electrode layer 70D formed on the other side surface thereof.

In this case, the first electrode layer 70A and the third electrode layer 70C may have the same polarity and the second electrode layer 70B and the fourth electrode layer 70D may have the same polarity and may have polarity different from the first electrode layer 70A.

The electronic component 100A according to another example embodiment of the present disclosure includes a first terminal 80A and a second terminal 80B. The first terminal 80A may be connected to the first plate-like element 60A and the second terminal 80B may be connected to the second plate-like element 60B.

The electronic component 100A according to another example embodiment of the present disclosure may further include a connecting terminal 85 electrically connecting the first plate-like element 60A and the second plate-like element 60B.

For example, the connecting terminal 85 may be connected to the first electrode layer 70A and the fourth electrode layer 70D to connect the first plate-like element 60A and the second plate-like element 60B in series. In this case, the first terminal 80A may be connected to the second electrode layer 70B and the second terminal 80B may be connected to the third electrode layer 70C.

On the other hand, the connecting terminal 85 may also be connected to the second electrode layer 70B and the third electrode layer 70D to connect between the first plate-like element 60A and the second plate-like element 60B in series. In this case, the first terminal 80A may be connected to the first electrode layer 70A and the second terminal 80B may be connected to the fourth electrode layer 70D.

The electronic component 100A may further include a coated or coating member 90 that at least partially encloses the plate-like element parts 60A and 60B, the first terminal 80A, the second terminal 80B, and the connecting terminal 85. The coated member 90 may have a shape corresponding to an outer circumferential surface of the plate-like element parts 60A and 60B. In this case, the electronic component 100A may be manufactured by molding the first plate-like element 60A and the second plate-like element 60B into the coated member 90 in the state in which the first plate-like element 60A and the second plate-like element 60B are connected in series. Further, the electronic part 100A may further include first and second filter members 95A and 95B including insertion holes 951A and 951B respectively for receiving bending parts 802A and 802B respectively of terminals 80A and 80B, respectively.

That is, the electronic component 100A according to another exemplary embodiment of the present disclosure may satisfy the high level of standard by securing the sufficient creepage distance L_{B} and clearance distance L_{A}. Further, the first plate-like element 60A and the second plate-like element 50B that have small capacity may be connected in series and thus sufficient capacity may be secured.

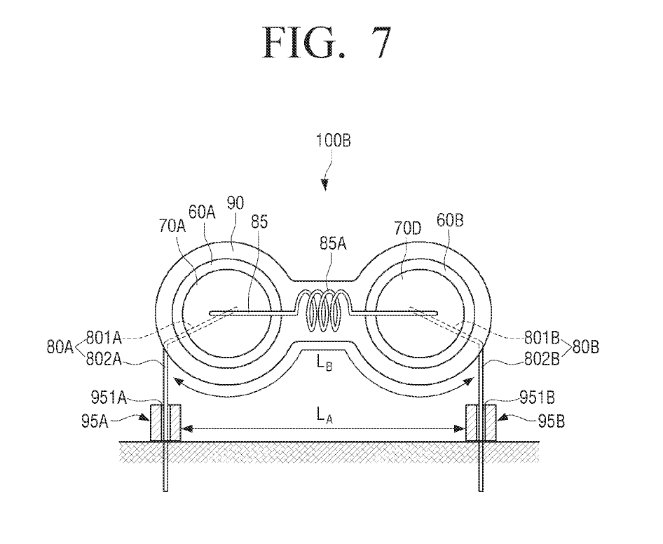

FIG. 7 is a front view illustrating example electronic parts according to another example embodiment of the present disclosure. Hereinafter, the difference from the electronic component according to the foregoing example embodiment of the present disclosure will be mainly described and the omitted description may be replaced by the content described with reference to FIGS. 1 to 6.

An electronic component 100B according to another example embodiment of the present disclosure may include the plate-like element parts 60A and 60B, the first terminal 80A, the second terminal 80B, the coated member 90, the first filter member 95A, the second filter member 95B, and the connecting terminal 85.

The cross sections of the first plate-like element 60A and the second plate-like element 60B may have a disk shape and the first plate-like element 60A and the second plate-like element 60B may have the same shape and may be disposed at a position where they correspond to each other.

The first plate-like element 60A may be provided with the first electrode layer 70A and the second electrode layer 70B. The first electrode layer 70A may be formed on one surface of the first plate-like element 60A and the second electrode layer 70B may be formed on the other surface of the first electrode layer 70A. The second plate-like element 60B may be provided with the third electrode layer 70A and the fourth electrode layer 70D. The third electrode layer 70C may be formed on one surface of the second plate-like element 60B and the fourth electrode layer 70D may be formed on the other surface of the third electrode layer 70C.

The connecting terminal 85 may electrically connect the first plate-like element 60A and the second plate-like element 60B. Further, the connecting terminal 85 may include a coil part 85A formed in at least a portion between the first plate-like element 60A and the second plate-like element 60B.

That is, the electronic component 100B according to another example embodiment of the present disclosure may secure the sufficient creepage distance L_{B} and clearance distance L_{A}. Further, the first plate-like element 60A and the second plate-like element 50B that have small capacity may be connected in series and thus sufficient capacity may be secured. Further, it is possible to minimize the generation of leakage inductance through the coil part 85A provided at the connecting terminal 85.

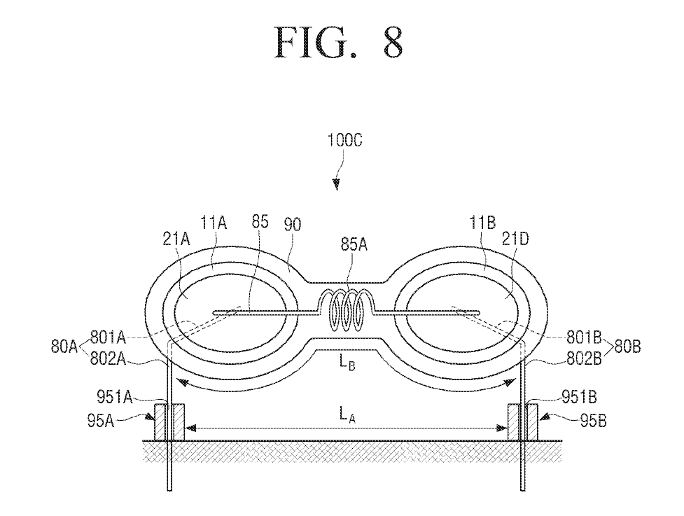

FIG. 8 is a front view illustrating electronic parts according to another example embodiment of the present disclosure. Hereinafter, the difference from the electronic component according to the foregoing example embodiment of the present disclosure will be mainly described and the omitted description may be replaced by the content described with reference to FIGS. 1 to 7.

Referring to FIG. 8, an electronic component 100C according to another example embodiment of the present disclosure may include plate-like element parts 11A and 11B, the first terminal 80A, the second terminal 80B, the coated member 90, a first filter member 90A, a second filter member 90B, and the connecting terminal 85.

The first plate-like element 11A and the second plate-like element 11B may have an oval shape and the first plate-like element 11A and the second plate-like element 11B may have the same shape and may be disposed at a position where they correspond to each other.

The first plate-like element 11A may have a first electrode layer 21A formed on one surface thereof and have a second electrode layer 21B formed on the other side surface thereof. The second plate-like element 11B may have a third electrode layer 21C formed on one surface thereof and have a fourth electrode layer 21D formed on the other side surface thereof. The connecting terminal 85 may electrically connect between the first plate-like element 11A and the second plate-like element 11B. Further, the connecting terminal 85 may have the coil part 85A formed in at least a portion between the first plate-like element 11A and the second plate-like element 11B.

That is, the electronic component 100C according to another exemplary embodiment of the present disclosure may secure the sufficient creepage distance L_{B} and clearance distance L_{A}. Further, the first plate-like element 11A and the second plate-like element 11B that have small capacity may be connected in series and thus sufficient capacity may be secured. Further, it is possible to minimize the generation of leakage inductance through the coil part 85A provided at the connecting terminal 85.

Hereinabove, various example embodiments of the present disclosure are individually described, but each example embodiment need not necessarily be implemented alone and therefore the configurations and operations of each example embodiment may also be implemented in combination with at least one other example embodiment.

Although various example embodiments of the present disclosure have been disclosed for illustrative purposes, those skilled in the art will appreciate that various modifications, additions and substitutions are possible, without departing from the scope and spirit of the disclosure as disclosed in the accompanying claims. Accordingly, such modifications, additions and substitutions should also be understood to fall within the scope of the present disclosure.

What is claimed is:

1. An electronic part, comprising:
at least one plate; and
first and second terminals each connected to the plate,
wherein the electronic part is mounted in a PCB through the first and second terminals and a creepage distance between the first terminal and the second terminal is greater than a clearance distance between the first terminal and the second terminal.

2. The electronic part of claim 1, wherein the plate comprises an oval shape.

3. The electronic part as claimed in claim 2, wherein the plate further includes:
a first electrode layer formed on one surface of the plate; and
a second electrode layer formed on another side surface of the plate different from the one surface.

4. The electronic part as claimed in claim 3, wherein the first terminal is connected to the first electrode layer and the second terminal is connected to the second electrode layer.

5. The electronic part as claimed in claim 4, wherein the first terminal includes a first connecting end portion connected to the first electrode layer and a first bending portion extending from the first connecting portion and configured to be bent toward the PCB, and
the second terminal includes a second connecting end portion connected to the second electrode layer and a second bending portion extending from the second connecting portion and configured to be bent toward the PCB.

6. The electronic part as claimed in claim 5, wherein the plate has a long axis in a vertical direction with respect to the first and second bending parts

7. The electronic part as claimed in claim 2, further comprising:
a first filter into which a portion of the first terminal is inserted and a second filter into which a portion of the second terminal is inserted.

8. The electronic part as claimed in claim 7, wherein the first filter and the second filter comprise a ferrite core.

9. The electronic part as claimed in claim 1, wherein the plate includes:
a first plate including a first electrode layer formed on one surface thereof and a second electrode layer formed on another surface of the plate different from the first electrode layer; and
a second plate-like element including a third electrode layer formed on one surface thereof and a fourth electrode layer formed on another surface of the second plate different from the third electrode layer, and
the first terminal being connected to the first plate and the second terminal being connected to the second plate.

10. The electronic part as claimed in claim 9, further comprising:
a connecting terminal connecting the first plate and the second plate in series.

11. The electronic part as claimed in claim 10, wherein the first electrode layer and the third electrode layer have the same polarity, and
the second electrode layer and the fourth electrode layer have the same polarity different from the first electrode layer.

12. The electronic part as claimed in claim 11, wherein the connecting terminal is connected to the second electrode layer and the third electrode layer,
the first terminal is connected to the first electrode layer, and
the second terminal is connected to the fourth electrode layer.

13. The electronic part as claimed in claim 9, wherein the first plate and the second plate have a disk shape and are disposed to correspond to each other.

14. The electronic part as claimed in claim 9, wherein the first plate and the second plate are positioned at a preset interval from one another.

15. The electronic part as claimed in claim 14, further comprising:
a connecting terminal connecting the first plate and the second plate in series,
wherein the connecting terminal comprises a coil part provided between the first plate and the second plate.

16. The electronic part as claimed in claim 9, further comprising:
a first filter into which the first terminal is inserted; and
a second filter into which the second terminal is inserted.

17. The electronic part as claimed in claim 16, wherein the first filter and the second filter comprise a ferrite core.

18. The electronic part as claimed in claim 1, wherein the creepage distance is greater by 1.48 times or more than the clearance distance.

19. The electronic part as claimed in claim 5, wherein the first bending part and the second bending part are positioned at a same distance from a center of the plate.

20. The electronic part as claimed in claim 7, wherein a portion of the first and second bending parts is inserted into the first filter and the second filter, respectively.
